(19) United States
(12) Patent Application Publication
(10) Pub. No.: US 2006/0016473 A1
(43) Pub. Date: Jan. 26, 2006

(54) Dye-sensitized solar cell employing photoelectric transformation electrode and a method of manufacturing thereof

(76) Inventors: Jae-Man Choi, Suwon-si (KR); Ji-Won Lee, Suwon-si (KR); Wha-Sup Lee, Suwon-si (KR); Kwang-Soon Ahn, Suwon-shi (KR); Joung-Won Park, Suwon-si (KR); Byong-Cheol Shin, Suwon-si (KR)

Correspondence Address: MCGUIREWOODS, LLP, 1750 TYSONS BLVD, SUITE 1800, MCLEAN, VA, 22102, US

(21) Appl. No.: 11/167,156

(22) Filed: Jun. 28, 2005

(30) Foreign Application Priority Data
Jun. 29, 2004 (KR) 10-2004-0049728

(51) Int. Cl. H01L 31/00

(52) U.S. Cl. 136/263; 438/82; 438/85

(57) ABSTRACT

A dye-sensitized solar cell using a photoelectric transformation electrode. The solar cell includes a semiconductor electrode, a counter electrode provided opposite to the semiconductor electrode, an oxide semiconductor layer provided between the semiconductor electrode and the counter electrode and having a dye adsorbed thereon, an electrolyte solution provided between the semiconductor electrode and the counter electrode, a spacer partitioning a space defined between the semiconductor electrode and the counter electrode to form at least one unit cell, and a metal wire at least partially patterned between the at least one unit cells.

### CROSS REFERENCE TO RELATED APPLICATION

This application claims the priority of Korean Patent Application No. 0.10-2004-0049728, filed on Jun. 29, 2004, in the Korean Intellectual Property Office, which is hereby incorporated by reference for all purposes as if fully set forth herein.

### BACKGROUND OF THE INVENTION

1. Field of the Invention

The present invention relates to a solar cell, and more particularly, to a dye-sensitized solar cell including a transition metal oxide nanoparticle semiconductor electrode. Specifically, the present invention relates to a dye-sensitized solar cell including a transition metal oxide nanoparticle semiconductor electrode, in which metal wires are provided in spaces between unit cells constituting a module, which increases the transfer rate of excited electrons into the semiconductor electrode and significantly decreases a reduction in photoelectric transformation efficiency that may be caused during fabrication of a large-scale module, thereby increasing photocurrent.

2. Description of the Related Art

Currently available dye-sensitized solar cells, commonly called “Graetzel cells,” are photoelectrochemical solar cells using a photosensitive dye molecule and an oxide semiconductor made of titanium oxide nanoparticles. The dye-sensitized solar cells have a lower manufacturing cost relative to a conventional silicon-based solar cells, and include a transparent electrode that enables them to be used in windows installed in external walls of buildings, glasshouses, etc. Therefore, a lot of research has been conducted relating to dye-sensitized solar cells.

FIG. 1 is a schematic view illustrating a conventional dye-sensitized solar cell. Referring to FIG. 1, a conventional dye-sensitized solar cell includes a first electrode 1 and a second electrode 2. A porous film 3, in which a dye 5 is adsorbed, and an electrolyte 4 are provided between the first electrode 1 and the second electrode 2. When sunlight is incident in the dye-sensitized solar cell, photons are absorbed in the dye 5. Electrons are excited in the dye 5 and injected into a conduction band of transition metal oxide constituting the porous film 3. After the injection, the electrons are transported or attracted to the first electrode 1 and then the electrons transfer electric energy to an external circuit. The electrons, which have fallen to a lower energy level by the energy transfer, are subsequently sent to the second electrode 2. The dye 5 is returned to an original state after the number of electrons corresponding to the number of the electrons injected into the conduction band of the transition metal oxide of the porous film 3 are supplied from the electrolyte 4. The electrolyte 4 receives electrons from the second electrode 2 using an oxidation and reduction, i.e., redox, reaction and then supplies the electrons to the dye 5.

Conventional solar cells as described above have a low manufacturing cost and are environmental friendly. However, energy transition efficiency may be lowered by recombination of electrons and holes at an interface between a first electrode coated with a porous film and an electrolyte, which restricts practical application. In view of this problem, a dye-sensitized solar cell with the structure shown in FIG. 2 has been proposed.

Referring to FIG. 2, a solar cell has a sandwich structure in which two plate electrodes, i.e., a first electrode 10 and a second electrode 20 face with each other. A porous film 30 made of nanoparticles is coated on or directly on a surface of the first electrode 10. A photosensitive dye, in which electrons are excited by absorbing visible light, is attached to surfaces of the nanoparticles of the porous film 30. The first electrode 10 and the second electrode 20 are bonded and fixed by a support 60 and a space defined between the first electrode 10 and the second electrode 20 is filled with a redox electrolyte 40.

As the first electrode 10, there is used a transparent plastic substrate or a glass substrate 11 coated with a conductive film 12 made of indium tin oxide, etc. A buffer layer 50 made of at least two layers is formed on a surface of the conductive film 12 of the first electrode 10. The buffer layer 50 includes a first layer 51 made of a material with a conduction band energy level lower than a conduction band energy level of the porous film 30 and a second layer 52 made of a material with a conduction band energy level higher than the conduction band energy level of the first layer 51. The first layer 51 and the second layer 52 are made of a material with a particle size smaller than the nanoparticles constituting the porous film 30, and thus, have a dense structure. The first layer 51 serves to improve interface characteristics between the first electrode 10 and the electrolyte 40, and thus, to reduce hole-electron recombination at the interface between the first electrode 10 and the electrolyte 40, thereby enhancing electron trapping or collection characteristics.

In the above-described dye-sensitized solar cells, the photoelectric transformation efficiency of the solar cells is proportional to the amount of electrons generated by sunlight absorption. In this regard, to increase the photoelectric transformation efficiency, the following methods have been proposed: methods of increasing the reflectivity of a platinum electrode, increasing sunlight absorption using a plurality of micrometer-sized semiconductor oxide photo-scattering particles, or increasing the absorption of photons into a dye, to increase the amount of electrons; a method of preventing annihilation of excited electrons by electron-hole recombination; a method of improving sheet resistance of an interface and an electrode to increase the transfer rate of excited electrons, etc. However, photoelectric transformation efficiency may be lowered during fabrication of large-scale solar cells or modules, which restricts practical applications and renders large-scale solar cell fabrication difficult.

### SUMMARY OF THE INVENTION

The present invention provides a dye-sensitized solar cell in which metal wires are provided on a transparent electrode that is used as an oxide semiconductor electrode to increase a transfer rate of an electron and thus improve reduction in photoelectric transformation efficiency.

In particular, the present invention discloses a dye-sensitized solar cell in which metal wires are provided in a spacer to prevent direct contact of the metal wires with unit cells constituting a module. Therefore, a short circuit by direct contact of the metal wires with an electrolyte solution or an oxide semiconductor layer and corrosion of the metal wires by the electrolyte solution is prevented. Further, there is no need to add a blocking layer, which is required for a common metal wire layer. The present invention discloses a dye-sensitized solar cell using a photoelectric transformation electrode, the solar cell includes a semiconductor electrode, a counter electrode provided opposite to the semiconductor electrode, an oxide semiconductor layer provided between the semiconductor electrode and the counter electrode and having a dye adsorbed thereon, an electrolyte solution provided between the semiconductor electrode and the counter electrode, a spacer partitioning a space defined between the semiconductor electrode and the counter electrode to form at least one unit cell, and a metal wire at least partially patterned in spaces defined between the at least one unit cell.

The present invention discloses a method of manufacturing a dye-sensitized solar cell that uses a photoelectric transformation electrode, the method including preparing a semiconductor substrate having a conductive layer, determining a position on the conductive layer for a spacer to be provided to define a unit cell, forming a metal wire in the determined position on the conductive layer of the semiconductor substrate, forming the spacer over the metal wire, and filling the unit cell with an electrolyte solution, wherein the spacer insulates the metal wire from the electrolyte solution.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

FIG. 1 is a schematic view illustrating a conventional dye-sensitized solar cells.

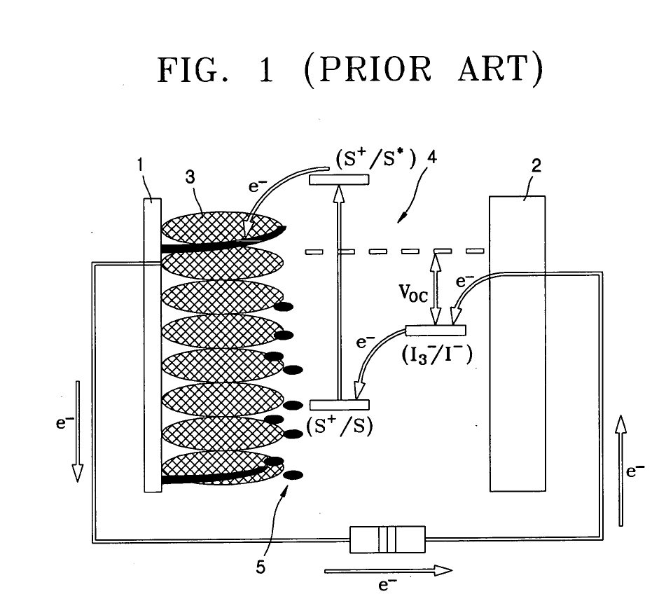

FIG. 2 is a schematic sectional view illustrating dye-sensitized solar cells.

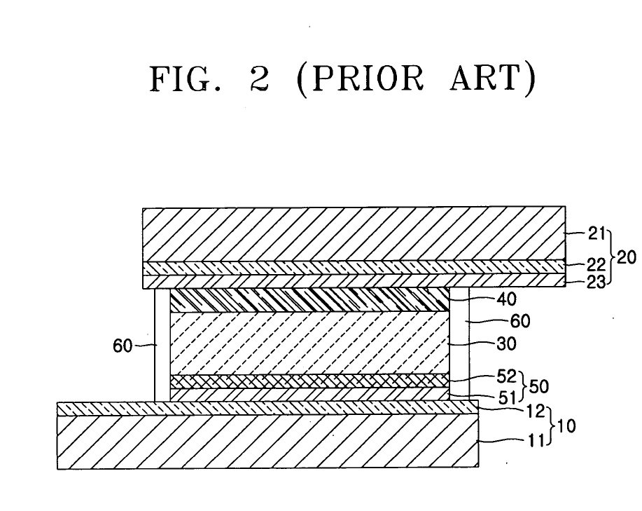

FIG. 3 is a schematic sectional view illustrating a dye-sensitized solar cell according to an embodiment of the invention.

FIG. 4 is a perspective view of the solar cell of FIG. 3.

### DETAILED DESCRIPTION OF EMBODIMENTS OF THE INVENTION

Dye-sensitized solar cells according to embodiments of the invention are described below with reference to the accompanying drawings.

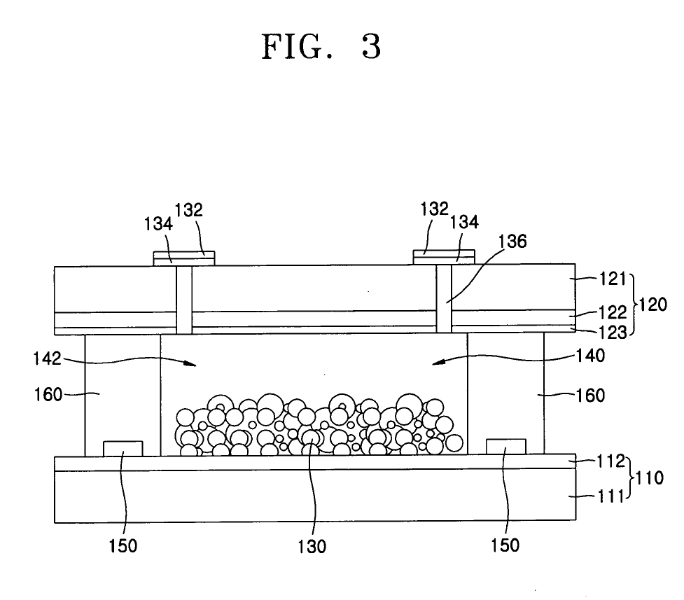

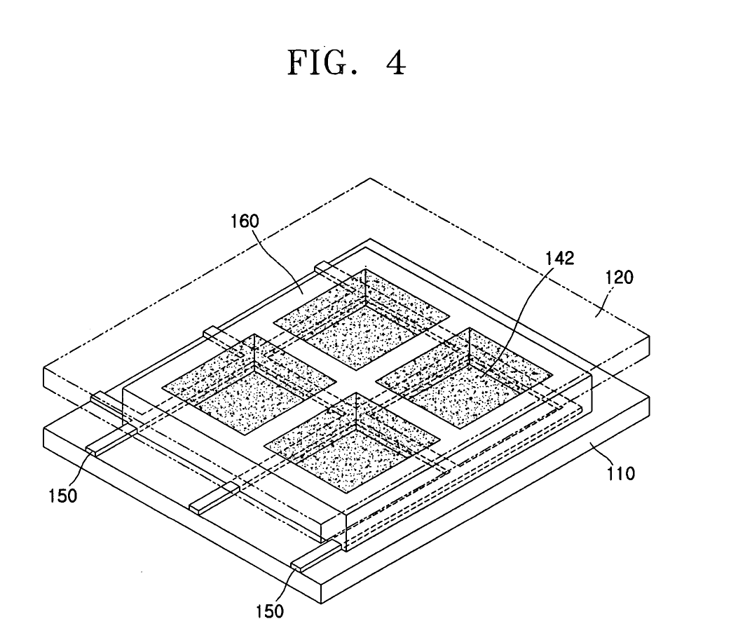

FIG. 3 is a schematic sectional view illustrating a dye-sensitized solar cell according to an embodiment of the invention and FIG. 4 is a schematic perspective view of the solar cell of FIG. 3.

Referring to FIG. 3 and FIG. 4, a dye-sensitized solar cell using a photoelectric transformation electrode has a sandwich like structure in which two plate electrodes, i.e., a semiconductor electrode 110 and a counter electrode 120, face with each other. For example, the two electrodes may be substantially parallel with each other. An oxide semiconductor layer 130 having a dye adsorbed therein, is provided between the semiconductor electrode 110 and the counter electrode 120. In particular, the oxide semiconductor layer 130 is formed on a surface of the semiconductor electrode 110.

A redox electrolyte solution 140 is provided or filled in a space between the semiconductor electrode 110 and the counter electrode 120. A spacer 160, e.g., support, serving as a partition wall is provided in the space between the semiconductor electrode 110 and the counter electrode 120, so that the space defined between the semiconductor electrode 110 and the counter electrode 120 is partitioned to form unit cells 142 separated from each other by a predetermined distance. Metal wires 150 are patterned between the unit cells 142, i.e., in spaces defined between the unit cells 142. Thus, the number of unit cells 142 is determined by the number of partitioned spaces provided between the semiconductor electrode 110 and the counter electrode 120.

The semiconductor electrode 110 includes a semiconductor electrode substrate 111 and a transparent conductive film 112 for a semiconductor electrode formed on a surface of the semiconductor electrode substrate 111. The semiconductor electrode substrate 111 may be made of a transparent material, for example, a glass, polyethyleneterephthalate (PET), polyethylenenaphthalate (PEN), or polycarbonate (PC), and may be used as a cathode of a solar cell. The transparent conductive film 112 coated on the surface of the semiconductor electrode substrate 111 may be made of a transparent conductive material, such as indium tin oxide (ITO) or fluorine tin oxide (FTO). Therefore, sunlight can be incident in and transmitted through the transparent semiconductor electrode 110 having the structure discussed above.

Meanwhile, the counter electrode 120 positioned opposite to the semiconductor electrode 110 includes a counter electrode substrate 121, a transparent conductive film 122 for a counter electrode formed on a surface of the counter electrode substrate 121, and a conductive film 123 formed on a surface of the transparent conductive film 122, wherein the conductive filing includes platinum or a noble metal.

The counter electrode substrate 121 may be is a transparent plastic substrate, including a glass substrate or one of PET, PEN, PC, polypropylene (PP), polyimide (PI), and tri-acetyl-cellulose (TAC). The transparent conductive film 122 for a counter electrode may be a transparent and conductive film made of ITO or FTO.

The conductive film 123 formed on the surface of the transparent conductive film 122 may be a conductive film made of platinum that is obtained by wet coating of a solution of H₂PtCl₆ in an organic solvent (methanol, ethanol, isopropylalcohol, etc.) on the transparent conductive film 122. The wet coating is followed by high-temperature treatment at 400° C., e.g., heat treating, or more in air or an oxygen atmosphere or by electroplating or physical vapor deposition (PVD) (techniques such as sputtering, e-beam evaporation, etc.). Here, the wet coating may be performed by spin coating, dip coating, or flow coating.

Thus, in a nonlimiting embodiment of the invention, a solar cell includes the semiconductor electrode 110 on which photosensitive dye molecules are adsorbed, the counter electrode 120 in which the conductive film 123 containing platinum is coated, and the redox electrolyte solution 140 filled between the semiconductor electrode 110 and the counter electrode 120. The semiconductor electrode 110 includes the semiconductor electrode substrate 111 which may be a transparent conductive glass substrate coated with ITO or FTO. The metal wires 150 are arranged in the spacer 160. The spacer 160 provides a support structure, e.g., side support, for the oxide semiconductor layer 130 formed on the semiconductor electrode substrate 111 coated with the transparent conductive film 112. The spacer 160 is provided or installed to partition the space between the semiconductor electrode 110 and the counter electrode 120 and form unit cells 142 to be filled with the electrolyte solution 140, according to either a dry or wet method.

The semiconductor electrode 110 and the counter electrode 120 are attached by arranging the conductive film 123 including at least platinum and the oxide semiconductor layer 130 to face with each other and providing a polymer layer made of SURLYN (trade name of Dupont™) used as the spacer 160 on the metal wires 150, and then pressing the polymer layer used as the spacer 160 on the metal wires 150 when the same is at a temperature of approximately 100° C. The spacer 160 may be formed by various other techniques, such as by a dispenser method using one of various polymer adhesives, in addition to SURLYN.

For example, the redox electrolyte solution 140 is prepared by dissolving an iodine (I) source, i.e., 0.5M tetrapropylammonium iodide or 0.8M lithium iodide (LiI) and 0.05M iodine (I₂) in acetonitrille.

The metal wires 150 are isolated or separated from the electrolyte solution 140 filled in the unit cells 142 by the spacer 160. The metal wires 150 may be made of Au, Ag, Al, Pt, Cu, Fe, Ni, Ti, Zr, or an alloy of two or more of the foregoing metals.

According to an embodiment of the invention, the metal wires 150 may be formed by patterning a metal paste of one or more elements selected from Au, Ag, Al, Pt, Cu, Fe, Ni, Ti, and Zr by a known patterning method, such as a screen printing method, a printing method, or a dispenser method. Alternatively, the metal wires 150 may be formed by patterning a colloidal solution of one or more selected from Au, Ag, Al, Pt, Cu, Fe, Ni, Ti, and Zr by a screen printing method, a printing method, or a dispenser method.

In addition, the metal wires 150 may be formed by etching a metal film made of one or more elements selected from Au, Ag, Al, Pt, Cu, Fe, Ni, Ti, and Zr using a combination of a lithography process with one of chemical deposition, sputtering, and electrodeposition.

Thus, in a non-limiting example, to isolate the metal wires 150 from the electrolyte solution 140, the metal wires 150 are formed narrower than the spacer 160, e.g., metal wire is fully contained in the spacer 160. In other words, the metal wires 150 are formed such that they are buried in the spacer 160.

As shown in FIG. 4, the metal wires 150 surround the unit cells 142 since they are positioned in spaces that are formed to operate as boundaries to partition the unit cells. Since the metal wires 150 are formed to be buried in the spacer 160, either subsequently or during formation of the metal wires 150, even though the number of the unit cells 142 increases for fabrication of large-scale solar cells or modules, the metal wires 150 can be appropriately installed. With such an arrangement, the transfer rate of excited electrons into the semiconductor electrode 110 increases, thereby preventing a reduction in photoelectric transformation efficiency.

The metal wires 150 have a thickness or diameter of approximately 0.1 to 30 μm. The unit cells 142 are generally formed in a square or rectangular shape, however the invention is not limited thereto. The unit cells 142 may be formed having any predetermined shape. However, the metal wires 150 should be buried in the spacer 160 according to the shapes of the unit cells 142 partitioned by the spacer 160 so that the metal wires 150 are not exposed to the counter electrode 120 or the electrolyte solution 140.

For example, when the unit cells 142 are formed in a square shape, then a side length of each unit cell is in the range of approximately 0.1 to 30 mm. It is understood that there may be more than one unit cell 142. As shown in FIG. 3 and FIG. 4, the metal wires 150 are formed on the semiconductor electrode 110 along the spacer 160 partitioning the unit cells 142 in such a way to be buried in the spacer 160.

A method of manufacturing a dye-sensitized solar cell including a semiconductor electrode on which metal wires are formed according to the embodiment of the invention is described.

A semiconductor electrode substrate 111 is prepared. For example, the semiconductor electrode substrate 111 may be a substrate having a good transparency that is and capable of being used as a cathode of a solar cell, for example, a glass substrate, a PET substrate, a PEN substrate, or a PC substrate, or a substrate coated with a transparent conductive material such as ITO or FTO.

A position intended for a spacer 160, e.g. predetermined position, is determined on a conductive layer of the semiconductor electrode substrate that defines a position intended for an oxide semiconductor layer 130. The spacer 160 also prevents an electrode short circuit between unit cells 142 during fabrication of modules. The spacer 160 also defines a space between the semiconductor electrode 110 and the counter electrode 120 to be filled with an electrolyte solution. When the position intended for the spacer is determined, metal wires are formed having the same pattern or space as the spacer will be formed. The metal wires should be narrower than the spacer in order to prevent direct contact of the metal wires with the electrolyte solution by exposure of the metal wires.

The metal wires may be patterned according various methods and patterning techniques. According to an embodiment of the invention, the patterning is performed directly on a surface of the semiconductor electrode substrate. For example, the patterning may be performed using a paste or a colloidal solution of highly conductive metal particles selected from gold, silver, platinum, and an alloy thereof and applied to the surface using one of the following techniques, a screen printing technique, a printing technique, and a dispenser technique. Further, patterning may also be performed by combining a lithography process with a deposition process, such as chemical vapor deposition (CVD) or sputtering. Patterning may additionally be performed by etching a metal film formed by electrodeposition or electroplating.

When the metal wires 150 are patterned by any one of the above-described methods, an oxide semiconductor paste is coated or applied to a surface of the semiconductor electrode 110 between the metal wires and heated to form necking between oxide particles. A photosensitive dye is then absorbed into the resultant semiconductor electrode substrate structure, which completes the formation of the oxide semiconductor electrode 110. For example, the photosensitive dye may be selected from one of the following a complex compound of a metal such as Al, Pt, Pd, Eu, Pb, or Ir, wherein the photosensitive dye is preferably formed of a ruthenium dye (Ru-dye) molecule.

A counter electrode 120 is additionally prepared. The counter electrode 120 is formed by a wet coating process, e.g., spin coating, dip coating, or flow coating, of a transparent or glass substrate that coated with ITO or FTO or a transparent conductive polymer film having a solution of H₂PtCl₆ in an organic solvent, such as methanol, ethanol, isopropylalcohol, etc. followed by high temperature treatment at 400° C. or more in air or an oxygen atmosphere, or by coating a conductive film made of platinum on the glass substrate using electroplating or PVD, such as sputtering or e-beam evaporation.

The semiconductor electrode and the counter electrode are then attached or coupled by arranging or positioning the conductive film and the oxide semiconductor layer to face each other, e.g., parallel with each other, and a polymer layer, e.g, SURLYN, to form a spacer on the metal wires 150. about the polymer layer is then pressed on the metal wires 150 when the same is at a temperature of approximately 100° C. Alternatively, the spacer 160 may also be formed by a dispenser method using one of various polymer adhesives, in addition to SURLYN.

A redox electrolyte solution 140 is then supplied or filled in unit cells 142. The redox electrolyte solution 140 may be prepared by dissolving an iodine source, such as 0.5M tetrapropylammonium iodide or 0.8M LiI, and 0.05M I₂, in acetonitrile. The electrolyte solution thus prepared is then injected or supplied the unit cells 142 via an inlet 136 that is formed through the counter electrode. After the electrolyte solution 140 is supplied, the inlet is sealed or covered by a sealing portion 134. The sealing portion 134 may be made of an epoxy resin or SURLYN. A glass (see 132 of FIG. 3) for sealing the inlet is disposed on the sealing portion to thereby complete a solar cell. It is understood that multiple such inlets 136 may be formed into the counter electrode 120 to provide for the electrolyte solution 140.

According to a dye-sensitized solar cell described in at least the embodiments of the present invention discussed above, metal wires are arranged on a transparent electrode used as an oxide semiconductor electrode. Therefore, the transfer rate of excited electrons in a dye into the oxide semiconductor electrode can be increased, and thus, reduction in photoelectric transformation efficiency that may occur in fabrication of large-scale dye-sensitized solar cells or modules can be improved.

A dye-sensitized solar cell of the present invention exhibits approximately a 35% increase in photoelectric transformation efficiency as compared to a common solar cell without metal wires. Further, the metal wires are provided in a spacer, which prevents a short circuit from occurring between the oxide semiconductor electrode and a counter electrode and defines a space to be filled with an electrolyte. Therefore, there is no need to form a separate coating layer, often referred to as either a protective layer or blocking layer to prevent a short circuit from occurring between the metal wires and an electrolyte solution or an oxide layer and corrosion of the metal wires by the electrolyte solution.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A dye-sensitized solar cell with a photoelectric transformation electrode, the solar cell comprising:
a semiconductor electrode;
a counter electrode provided opposite to the semiconductor electrode;
an oxide semiconductor layer provided between the semiconductor electrode and the counter electrode and having a dye adsorbed thereon;
an electrolyte solution provided between the semiconductor electrode and the counter electrode;
a spacer partitioning a space defined between the semiconductor electrode and the counter electrode to form at least one unit cell; and
a metal wire at least partially patterned between the at least one unit cells.

2. The dye-sensitized solar cell of claim 1, wherein the metal wire is completely patterned in spaces defined between at least one unit cell.

3. The dye-sensitized solar cell of claim 1, wherein the semiconductor electrode comprises:
a semiconductor electrode substrate; and
a transparent conductive film formed on the semiconductor electrode substrate.

4. The dye-sensitized solar cell of claim 3, wherein the counter electrode comprises:
a counter electrode substrate;
a transparent conductive film formed on the counter electrode substrate; and
a conductive film formed on the transparent conductive film.

5. The dye-sensitized solar cell of claim 4, wherein the conductive film comprises platinum.

6. The dye-sensitized solar cell of claim 1, wherein the metal wire comprises a metal selected from the group consisting of Au, Ag, Al, Pt, Cu, Fe, Ni, Ti, and Zr, or an alloy of two or more of the foregoing metals.

7. The dye-sensitized solar cell of claim 6, wherein the metal wire is patterned by a screen printing method, a printing method, or a dispenser method using a metal paste comprising the metal or metal alloy.

8. The dye-sensitized solar cell of claim 6, wherein the metal wire is patterned by a screen printing method, a printing method, or a dispenser method using a colloidal solution comprising the metal or metal alloy.

9. The dye-sensitized solar cell of claim 6, wherein the metal wire is patterned by combining a lithography process with one of chemical deposition, sputtering, or electrodeposition to etch a film comprising the metal or metal alloy.

10. The dye-sensitized solar cell of claim 1, wherein the spacer isolates the metal wire from the electrolyte solution.

11. The dye-sensitized solar cell of claim 10, wherein the metal wire is narrower than the spacer.

12. The dye-sensitized solar cell of claim 10, wherein the metal wire is approximately 0.1 to 30 μm thick.

13. The dye-sensitized solar cell of claim 1, wherein the at least one unit cell is rectangular shaped.

14. The dye-sensitized solar cell of claim 13, wherein each side of each unit cell has a length of approximately 0.1 to 30 mm.

15. The dye-sensitized solar cell of claim 1, wherein the spacer is formed around the metal wire to insulate the metal wire from the electrolyte solution.

16. A method of manufacturing a dye-sensitized solar cell that uses a photoelectric transformation electrode, the method comprising:
preparing a semiconductor electrode having a conductive layer formed on a semiconductor electrode substrate;
determining a position on the conductive layer for a spacer to be provided to form a unit cell;
forming a metal wire at the determined position on the conductive layer;
forming the spacer over the metal wire; and
adding an electrolyte solution to the unit cell,
wherein the spacer insulates the metal wire from the electrolyte solution.

17. The method of claim 16, wherein the metal wire comprises a metal selected from the group consisting of Au, Ag, Al, Pt, Cu, Fe, Ni, Ti, and Zr, or an alloy of two or more of the foregoing metals.

18. The method of claim 16, further comprising:
patterning the metal wire on the conductive layer by a screen printing method, a printing method, or a dispenser method using a metal paste comprising the metal or metal alloy.

19. The method of claim 16, further comprising:
patterning the metal wire on the conductive layer by a screen printing method, a printing method, or a dispenser method using a colloidal solution comprising the metal or metal alloy.

20. The method of claim 16, further comprising:
patterning the metal wire on the conductive layer by combining a lithography process with one of chemical deposition, sputtering, or electrodeposition to etch a film comprising the metal or metal alloy.
